(19) United States
(12) Patent Application Publication
(10) Pub. No.: US 2026/0231435 A1
(43) Pub. Date: Aug. 6, 2026

(54) SEMICONDUCTOR DEVICE AND METHOD FOR FABRICATING THE SAME

(71) Applicant: SK hynix Inc., Gyeonggi-do (KR)

(72) Inventors: Jeong Myeong KIM, Gyeonggi-do (KR); Cha Deok DONG, Gyeonggi-do (KR); Keo Rock CHOI, Gyeonggi-do (KR)

(21) Appl. No.: 19/215,361

(22) Filed: May 22, 2025

(30) Foreign Application Priority Data
Feb. 3, 2025 (KR) 10-2025-0013114

(51) Int. Cl. H10B 63/00

(52) U.S. Cl. CPC H10B 63/22; H10B 63/80

(57) ABSTRACT

Disclosed are a semiconductor device, and a method for fabricating the same. The semiconductor device includes a plurality of memory cells. Each of the memory cells includes a memory layer, and a selector layer formed over the memory layer to select the memory layer. The selector layer includes an amorphous silicon layer that is doped with a dopant including at least one of arsenic (As) and germanium (Ge), and an intermediate layer, including a first metal-doped silicon nitride and a first metal nitride, formed over the selector layer.

### CROSS-REFERENCE TO RELATED APPLICATIONS

The present application claims priority under 35 U.S.C 119(a) to Korean Patent Application No. 10-2025-0013114, filed on Feb. 3, 2025, which is incorporated herein by reference in its entirety.

### BACKGROUND

### 1. Field

Embodiments of the present disclosure relate to a semiconductor technology, and more particularly, to a semiconductor device including a memory cell having a selector, and a method for fabricating the semiconductor device.

### 2. Description of the Related Art

Recent demands for miniaturization, low power consumption, high performance, and diversification of electronic devices require semiconductor devices capable of storing data in diverse electronic devices, such as computers, portable communication devices and the like. Researchers and the industry are studying to develop semiconductor devices that fulfill these requirements. Semiconductor devices that are being developed and investigated for these purposes include those capable of storing data by using the characteristics of switching between different resistance states according to the applied voltage or current, such as a Resistive Random Access Memory (RRAM), a Phase-change Random Access Memory (PRAM), a Ferroelectric Random Access Memory (FRAM), a Magnetic Random Access Memory (MRAM), an E-fuse and the like.

A memory device having a variable resistance element includes a selector as an element for selecting a particular cell among a plurality of memory cells that are arrayed, and the selector may be realized as a thin layer in the cell.

### SUMMARY

Embodiments of the present disclosure are directed to a semiconductor device that may have improved selector characteristics of a memory cell, and a method for fabricating the semiconductor device.

In accordance with an embodiment of the present disclosure, a semiconductor device includes a plurality of memory cells. Each of the memory cells includes a memory layer, and a selector layer formed over the memory layer to select the memory layer. The selector layer includes an amorphous silicon layer that is doped with a dopant including at least one of arsenic (As) and germanium (Ge), and an intermediate layer, including a first metal-doped silicon nitride and a first metal nitride, formed over the selector layer.

In accordance with another embodiment of the present disclosure, a method for fabricating a semiconductor device including a selector layer in a memory cell among a plurality of arrayed memory cells to control electrical access to the memory cell includes forming an amorphous silicon layer that is doped with a dopant including at least one of arsenic (As) and germanium (Ge) as the selector layer over a substrate; forming an intermediate layer including a first metal-doped silicon nitride and a first metal nitride over the selector layer; and performing an annealing process at a temperature lower than a temperature of crystallization of the amorphous silicon layer.

### BRIEF DESCRIPTION OF THE DRAWINGS

FIG. 1A is a perspective view illustrating a semiconductor device in accordance with an embodiment of the present disclosure.

FIG. 1B is a cross-sectional view illustrating the semiconductor device in accordance with the embodiment of the present disclosure.

FIG. 2 illustrates a structure of a selector unit in accordance with an embodiment of the present disclosure.

FIG. 3 illustrates an operation of the selector unit shown in FIG. 2.

FIGS. 4A to 4I are cross-sectional views illustrating a semiconductor device and a method for fabricating the same in accordance with an embodiment of the present disclosure.

FIGS. 5A to 5J are cross-sectional views illustrating a semiconductor device and a method for fabricating the same in accordance with another embodiment of the present disclosure.

### DETAILED DESCRIPTION

Hereinafter, the various embodiments of the present disclosure will be described in detail with reference to the attached drawings.

Embodiments of the present disclosure will be described below in more detail with reference to the accompanying drawings. The embodiments may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

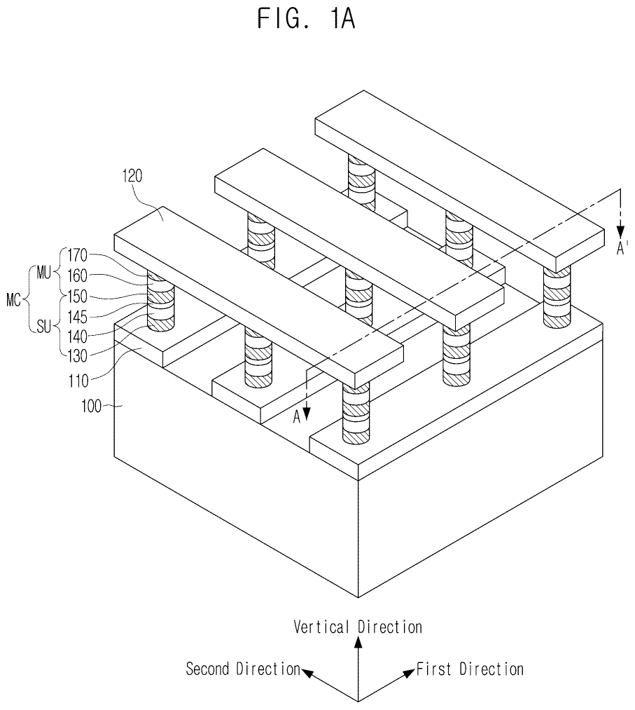

FIG. 1A is a perspective view illustrating a semiconductor device in accordance with an embodiment of the present disclosure. FIG. 1B is a cross-sectional view of the semiconductor device taken along a line A-A′ shown in FIG. 1A, in accordance with the embodiment of the present disclosure.

Referring to FIGS. 1A and 1B, the semiconductor device in accordance with the embodiment of the present disclosure may include a substrate 100, a plurality of first interconnections 110 disposed over the substrate 100 and extending in a first direction, a plurality of second interconnections 120 disposed over the first interconnections 110 and extending in a second direction that intersects with the first direction, and a plurality of memory cells MC disposed between the first interconnections 110 and the second interconnections 120 to overlap with the intersection areas between the first interconnections 110 and the second interconnections 120. The first direction and the second direction may denote directions substantially parallel to the surface of the substrate 100. Hereinafter, a direction substantially perpendicular to the surface of the substrate 100 may be referred to as a vertical direction.

The substrate 100 may include a semiconductor material such as silicon. Additionally, a required predetermined lower structure (not shown) may be formed in the substrate 100. For example, an integrated circuit for driving a first interconnection 110 and/or a second interconnection 120 may be formed in the substrate 100.

A plurality of first interconnections 110 may be disposed spaced apart from each other in the second direction. The first interconnection 110 may include diverse conductive materials, for example, metals such as platinum (Pt), tungsten (W), aluminum (Al), copper (Cu), tantalum (Ta) and the like, metal nitrides such as titanium nitride (TiN), tantalum nitride (TaN) and the like, or a combination thereof, and the first interconnection 110 may have a single-layer structure or a multi-layer structure.

A plurality of second interconnections 120 may be disposed spaced apart from each other in the first direction. The second interconnection 120 may include diverse conductive materials, for example, metals such as platinum (Pt), tungsten (W), aluminum (Al), copper (Cu), tantalum (Ta) and the like, metal nitrides such as titanium nitride (TiN), tantalum nitride (TaN) and the like, or a combination thereof, and the second interconnection 120 may have a single-layer structure or a multi-layer structure. One of the first interconnection 110 and the second interconnection 120 may function as a word line, and the other may function as a bit line. Although this embodiment of the present disclosure illustrates a cross-point structure of one layer, a cross-point structure of two or more layers may be stacked in a vertical direction.

Each of the memory cells MC may include a memory unit MU, which is a portion where data are actually stored, and a selector unit SU that controls access to the memory unit MU. For example, the memory cell MC may include a stacked structure of a first electrode layer 130, a selector layer 140, an intermediate layer 145, a second electrode layer 150, a memory layer 160, and a third electrode layer 170. Here, the selector unit SU may include the first electrode layer 130, the selector layer 140, the intermediate layer 145, and the second electrode layer 150, and the memory unit MU may include the second electrode layer 150, the memory layer 160, and the third electrode layer 170. The second electrode layer 150 may be shared by the selector unit SU and the memory unit MU.

The first electrode layer 130 and the third electrode layer 170 may be disposed at both ends of the memory cell MC, that is, at the bottom and the top, respectively, and may function to transfer a voltage or current required for an operation of the memory cell MC. The second electrode layer 150 may function to electrically connect the selector layer 140 and the memory layer 160 to each other, while physically separating them from each other. The first electrode layer 130, the second electrode layer 150, or the third electrode layer 170 may include diverse conductive materials, for example, metals such as platinum (Pt), tungsten (W), aluminum (Al), copper (Cu), tantalum (Ta), titanium (Ti) and the like, metal nitrides such as titanium nitride (TiN), tantalum nitride (TaN) and the like, or a combination thereof. Also, the first electrode layer 130, the second electrode layer 150, or the third electrode layer 170 may include a carbon electrode.

The memory layer 160 may function to store data in diverse ways. For example, the memory layer 160 may include a memory layer that stores different data by switching between different resistance states according to the voltage or current supplied through the upper and lower ends of the memory layer 160. The memory layer may have a single-layer structure or a multi-layer structure including diverse materials used in a Resistive Random Access Memory (RRAM), a Phase-change Random Access Memory (PRAM), a Ferroelectric Random Access Memory (FRAM), a Magnetic Random Access Memory (MRAM) and the like, for example, metal oxides such as transition metal oxides, perovskite-based materials and the like, phase-change materials such as chalcogenide-based materials and the like, ferroelectric materials, ferromagnetic materials, and the like.

The memory layer 160 may include a lower layer, a free layer, a tunnel barrier layer, a fixed layer, a magnetic compensation layer, and a capping layer. The free layer may be a layer that may store different data by having a changeable magnetization direction, and the free layer may also be called a storage layer. The fixed layer may have a fixed magnetization direction, which may be contrasted with the magnetization direction of the free layer, and the fixed layer may also be called a reference layer. The free layer and the fixed layer may have a single-layer structure or a multi-layer structure including a ferromagnetic material. For example, the free layer and the fixed layer may include an alloy mainly formed of iron (Fe), nickel (Ni) or cobalt (Co), such as an iron-platinum (Fe—Pt) alloy, an iron-palladium (Fe—Pd) alloy, a cobalt-palladium (Co—Pd) alloy, a cobalt-platinum (Co—Pt) alloy, a iron-nickel-platinum (Fe—Ni—Pt) alloy, a cobalt-iron-platinum (Co—Fe—Pt) alloy, a cobalt-nickel-platinum (Co—Ni—Pt) alloy, a iron-palladium (Fe—Pd) alloy, an iron-nickel-platinum (Fe—Ni—Pt) alloy, a cobalt-iron-platinum (Co—Fe—Pt) alloy, a cobalt-nickel-platinum (Co—Ni—Pt) alloy, a cobalt-iron-boron (Co—Fe—B) alloy and the like, or may include a stacked structure such as Co/Pt or Co/Pd. The magnetization directions of the free layer and the fixed layer may be substantially perpendicular to the surfaces of the layers. The magnetization direction of the free layer may vary between a top-down direction and a bottom-up direction, and the magnetization direction of the fixed layer may be fixed to the top-down direction or the bottom-up direction. The magnetization direction of the free layer may be changed due to the spin transfer torque. The relative positions of the free layer and the fixed layer may vary diversely with a tunnel barrier layer interposed between them. For example, the fixed layer may be disposed below the tunnel barrier layer, and the free layer may be disposed over the tunnel barrier layer.

The tunnel barrier layer may enable tunneling of electrons between the free layer and the fixed layer during a write operation that changes the resistance state of the variable resistor element, thereby changing the magnetization direction of the free layer. The tunnel barrier layer may include a dielectric oxide, such as magnesium oxide (MgO), calcium oxide (CaO), strontium oxide (SrO), titanium oxide (TiO), vanadium oxide (VO), niobium oxide (NbO), and the like. The free layer, the tunnel barrier layer, and the fixed layer may form a Magnetic Tunnel Junction (MTJ) structure.

The selector layer 140 may be realized as a thin layer in the memory cell, and may have a function of preventing current leakage that may occur between the memory cells MC that share the first interconnection 110 or the second interconnection 120 while controlling the electrical access to one memory cell among a plurality of memory cells that are arrayed. To this end, the selector layer 140 may have the threshold switching characteristics of blocking off the current or holding the current to hardly flow when the level of the voltage supplied to the upper and lower ends of the selector layer 140 is lower than a predetermined threshold voltage level, and then letting the current flow rapidly (e.g., unimpeded) at a voltage level which is equal to or higher than the threshold voltage level. The selector layer 140 may be turned on at a voltage level which is equal to or higher than the threshold voltage level, and may be turned off at a voltage level which is lower than the threshold voltage level. For example, the selector layer 140 may include a dielectric material into which a dopant is implanted. According to a particular embodiment of the present disclosure, the selector layer 140 may include an amorphous silicon layer that is doped with a Group-14 element of the periodic table, e.g., germanium (Ge). According to yet another embodiment of the present disclosure, the selector layer 140 may be doped with a Group-15 element of the periodic table, e.g., arsenic (As), by performing an additional ion implantation process into the amorphous silicon layer that is doped with the Group-14 element of the periodic table.

The intermediate layer 145 including a first metal-doped silicon nitride layer (SiₓN_{y}, where x ranges from 1 to 3 and y ranges from 1 to 4) and a first metal nitride layer may be disposed between the selector layer 140 and the second electrode layer 150. The intermediate layer 145 may complement the electrical characteristics of the selector layer 140 and increase the efficiency of transferring an electrical signal. In particular, a combination of the first metal-doped silicon nitride and the first metal nitride may simultaneously control the conductivity and insulation characteristics. Additionally, the intermediate layer 145 may control the flow of current generated during the operation of the selector layer 140 and may serve to form a conductive bridge. The combination of the first metal-doped silicon nitride layer and the first metal nitride layer included in the intermediate layer 145 may optimize the switching characteristics by controlling trap sites. As a result, the threshold voltage Vₜₕ and the forming voltage V_{f} of the selector layer 140 may be precisely controlled.

The first metal-doped silicon nitride layer may serve as a metal diffusion barrier layer, thereby preventing unnecessary metal migration in the inside of the structure of the selector layer 140 and providing thermal stability. The intermediate layer 145 may function as a portion of a serving layer to improve electrical stability and increase reliability at the interface between the selector layer 140 and the electrode.

The intermediate layer 145 may include a first metal-doped silicon nitride layer and a first metal nitride layer. Here, the first metal may be titanium (Ti), copper (Cu), silver (Ag), or gold (Au), and these metals have high chemical stabilities and long metal diffusion lengths.

In the case of the first metal-doped silicon nitride layer, metal doping may be performed at the trap sites formed in plural in silicon nitride (SiₓN_{y}, where x ranges from 1 to 3 and y ranges from 1 to 4), such as Si₃N₄, Si₂N₃ or SiN. This may enhance the conductive characteristics of the selector layer 140, and metal atoms may be effectively diffused into the silicon nitride by nitrogen (N₂) plasma that is formed by the Atomic Layer Deposition (ALD) process and the thermal effect.

The first metal nitride layer may include, for example, a metal nitride, such as titanium nitride (TiN), copper nitride (CuN), silver nitride (AgN) or gold nitride (AuN), which is deposited by an atomic layer deposition (ALD) process. This may provide a high electrical conductivity and heat resistance and may ensure the structural stability of the intermediate layer 145. For example, titanium nitride (TiN) may form a titanium-doped silicon nitride layer (SiₓN_{y}—Ti, where x ranges from 1 to 3 and y ranges from 1 to 4) under the condition of the N₂ plasma and an annealing process to enhance the operation of the selector layer 140. Trap sites and metal diffusion may be combined at the interface between the first metal-doped silicon nitride layer and the first metal nitride layer to form an artificial conductive bridge layer. For example, the intermediate layer 145 may serve as the conductive bridge layer. This interface may serve as a core region of electrical switching during the operation of the selector layer 140.

Although the memory cell MC of FIGS. 1A and 1B shows a stacked structure of the first electrode layer 130, the selector layer 140, the intermediate layer 145, the second electrode layer 150, the memory layer 160, and the third electrode layer 170, the embodiments of the present disclosure are not limited thereto, and the layer structure of the memory cell MC may be diversely modified. For example, at least one of the first electrode layer 130, the second electrode layer 150, and the third electrode layer 170 may be omitted. For example, the memory cell MC may include the selector layer 140, the first electrode layer 130 disposed below the selector layer 140, and the third electrode layer 170 disposed over the selector layer 140. For example, the first electrode layer 130 disposed below the selector layer 140 may include titanium nitride (TiN), and the third electrode layer 170 disposed over the selector layer 140 may include a carbon (C) electrode. Also, for example, the upper and lower positions of the selector layer 140 and the memory layer 160 may be switched with each other. Also, for example, the memory cell MC may further include one or more layers (not shown) to improve the characteristics or the process.

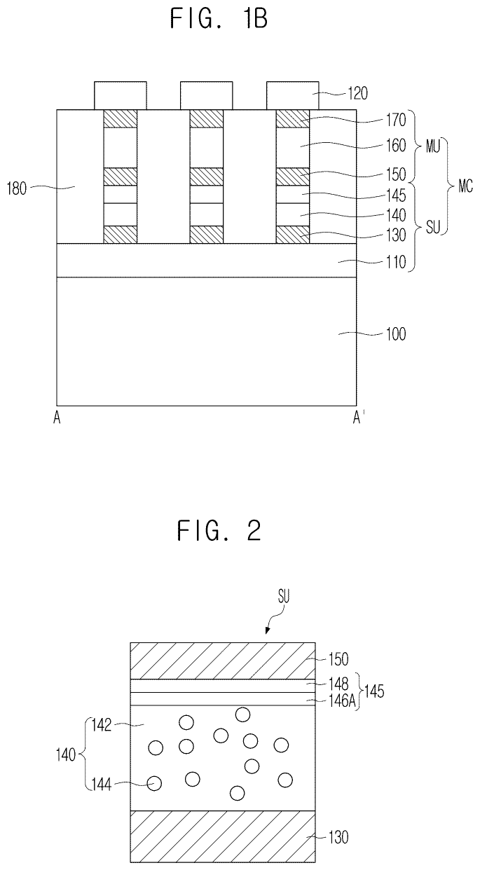

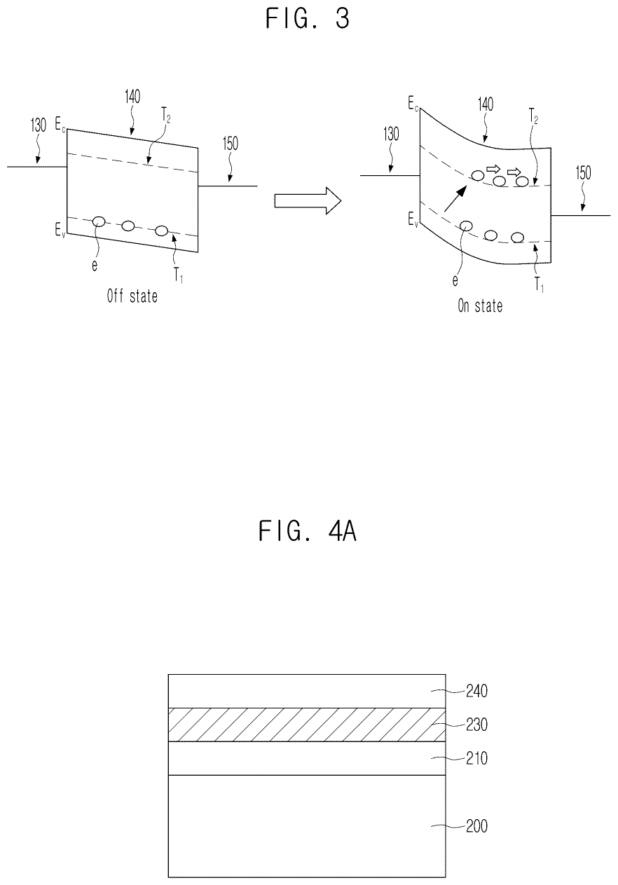

The selector unit SU including the selector layer 140 and the operation of the selector unit SU will be described in detail with reference to FIGS. 2 and 3 below.

FIG. 2 illustrates a structure of the selector unit SU in accordance with the embodiment of the present disclosure.

Referring to FIG. 2, the selector unit SU may include the first electrode layer 130, the selector layer 140, the intermediate layer 145, and the second electrode layer 150.

As described above, the first electrode layer 130 and the second electrode layer 150 may include diverse conductive materials, such as metals, metal nitrides, and the like. The first electrode layer 130 and the second electrode layer 150 may be formed of the same material to have the same work function. For example, the first electrode layer 130 and the second electrode layer 150 may include titanium nitride (TiN) having a work function of approximately 4.4 to 4.6 eV. However, the embodiments of the present disclosure are not limited thereto, and the first electrode layer 130 and the second electrode layer 150 may be formed of different materials to have different work functions.

The selector layer 140 may include a dielectric material layer 142 and a dopant 144 that is implanted into the dielectric material layer 142. The dielectric material layer 142 may include a dielectric material having a relatively wide band gap, for example, a dielectric material having a band gap of approximately 5.0 eV or higher. For example, the dielectric material layer 142 may include a silicon-containing dielectric material, such as silicon oxide, silicon nitride, silicon oxynitride and the like, a dielectric metal oxide, a dielectric metal nitride, or a combination thereof. For example, an oxide layer such as silicon dioxide (SiO₂) may be formed by mixing a source gas including silicon (Si) and oxygen (O) through a method such as Chemical Vapor Deposition (CVD), Physical Vapor Deposition (PVD), or Atomic Layer Deposition (ALD). There may be a deep trap whose energy level is closer to the energy level of a valence band than to the energy level of a conduction band of the dielectric material layer 142 in the dielectric material layer 142. The dopant 144 may serve to create a shallow trap that provides a path for conductive carriers, such as electrons or holes, to migrate in the dielectric material layer 142. The shallow trap may have an energy level which is closer to the energy level of a conduction band than to the energy level of a valence band of the dielectric material layer 142. The dopant that is doped into the selector layer 140 may include an N-type or P-type dopant and may be implanted by an ion implantation process. For example, when the dielectric material layer 142 contains silicon, the dopant 144 may include a Group-14 element of the periodic table having a d electron in the orbital electron configuration. For example, the dopant 144 may include a Group-14 element of the periodic table, such as carbon (C), silicon (Si), germanium (Ge), or tin (Sn). Also, when the dielectric material layer 142 contains silicon (Si), the dopant 144 may further include a Group-15 element of the periodic table having a different valence from the valence of silicon (Si). For example, the dopant 144 may include a Group-15 element of the periodic table, such as nitrogen (N), phosphorus (P), arsenic (As), or antimony (Sb), together with a Group-14 element of the periodic table. For example, the dopant 144 may include germanium (Ge). The dopant 144 may further include arsenic (As) together with germanium (Ge).

The concentration of the dopant and the ratio of amorphous silicon in the doped amorphous silicon layer may vary greatly according to the process conditions. The concentration of the dopant may be controlled by controlling the flow rates and hydraulic pressures of diborane (B₂H₆) and silane gas (SiₓH_{y}). For example, when the flow rate of diborane is increased, the concentration of the dopant may be increased, and conversely, when the flow rate of silane gas is increased, the ratio of amorphous silicon may be increased. When a doped amorphous silicon layer is generated by reacting diborane and silane gases under the temperature condition of approximately 300° C., the dopant 144 may have a concentration of approximately 10 to 30 wt % in the doped amorphous silicon layer, and the amorphous silicon may have a concentration of approximately 90 to 70 wt %. When the doped amorphous silicon layer is generated by reacting diborane and silane gases under the temperature condition of approximately 400° C., the diffusion of the dopant may become more active so that the dopant may be more easily doped into the amorphous silicon layer. Therefore, in this case, the dopant 144 may have a concentration of approximately 30 to 90 wt % in the doped amorphous silicon layer, and the amorphous silicon may have a concentration of approximately 70 to 10 wt %.

The intermediate layer 145 may be disposed between the selector layer 140 and the second electrode layer 150, thereby serving as an additional passivation layer on the surface of the selector layer 140 and improving the electrical characteristics. The intermediate layer 145 may protect the selector layer 140 physically and chemically, thereby protecting the selector layer from an external environment, such as oxidation and moisture. The intermediate layer 145 may be formed by combining the first metal-doped silicon nitride layer 146A and the first metal nitride layer 148. In particular, since the first metal-doped silicon nitride has excellent high-temperature stability and durability, it may ensure long-term reliability of the selector layer. The intermediate layer 145 may improve the switching characteristics of the selector layer 140 by optimizing the conductive path and uniformizing the current density. For example, a metal nitride such as titanium nitride (TiN), copper nitride (CuN), silver nitride (AgN) or gold nitride (AuN) may adjust the electrical characteristics of the selector layer 140 and contribute to stably maintaining the threshold voltage Vₜₕ of the selector layer 140.

The intermediate layer 145 may also function to suppress the diffusion of metal ions from the second electrode layer 150 to the selector layer 140. This may facilitate preventing excessive metal doping of the selector layer 140 and maintain desired electrical characteristics. Additionally, the intermediate layer 145 may lower the interface resistance between the selector layer 140 and the second electrode layer 150 and optimize the current flow. This may improve the switching characteristics of the selector layer 140 and the efficiency of the device. Also, by using the Atomic Layer Deposition (ALD) technique during the deposition of the first metal nitride, the intermediate layer 145 may be formed smoothly and uniformly, thereby significantly improving the interface characteristics. The first metal nitride layer of the intermediate layer 145 may provide thermal stability in a high-temperature process and may prevent structural strain of the selector layer 140.

The operation of this selector unit SU may be described below with reference to FIG. 3.

FIG. 3 illustrates an operation of the selector unit SU shown in FIG. 2. Referring to FIG. 3, in the off-state where no voltage is applied to the selector unit SU, conductive carriers, for example, electrons (e), may be trapped in the deep trap T₁ of the selector layer 140.

When a voltage which is equal to or higher than the threshold voltage is applied to the selector unit SU of the off-state through the first electrode layer 130 and the second electrode layer 150, an on-state in which current flows through the selector unit SU may be realized. To be specific, when a voltage which is equal to or higher than the threshold voltage is applied to the selector unit SU, the conductive carriers trapped in the deep trap T₁ may jump to a shallow trap T₂ by thermal emission or tunneling, and a conductive path coupling the first electrode layer 130 and the second electrode layer 150 may be created as the conductive carriers migrating through the shallow trap T₂.

When the voltage applied to the selector unit SU of the on-state is decreased, the number of conductive carriers migrating from the deep trap T₁ to the shallow trap T₂ may also be decreased (for example, substantially reduced) to turn off the selector unit SU again.

In this manner, the selector unit SU may be turned on and off.

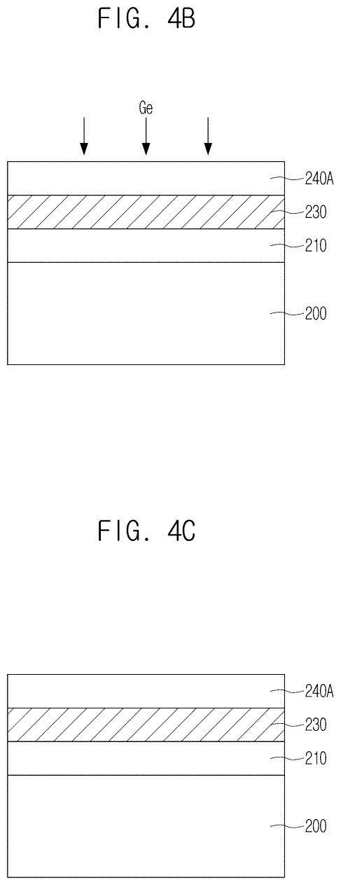

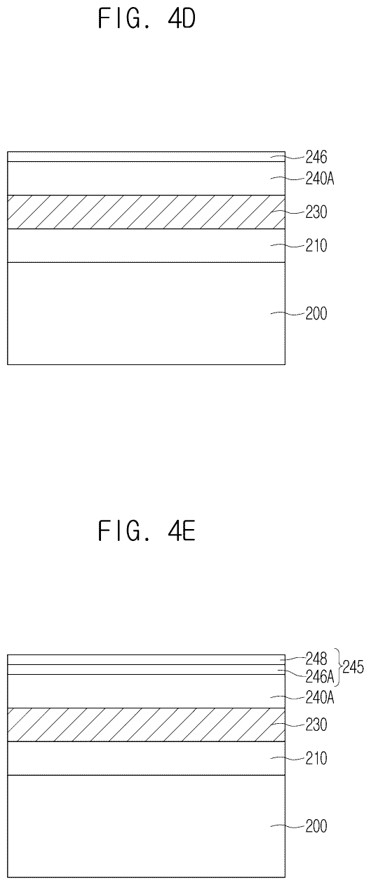

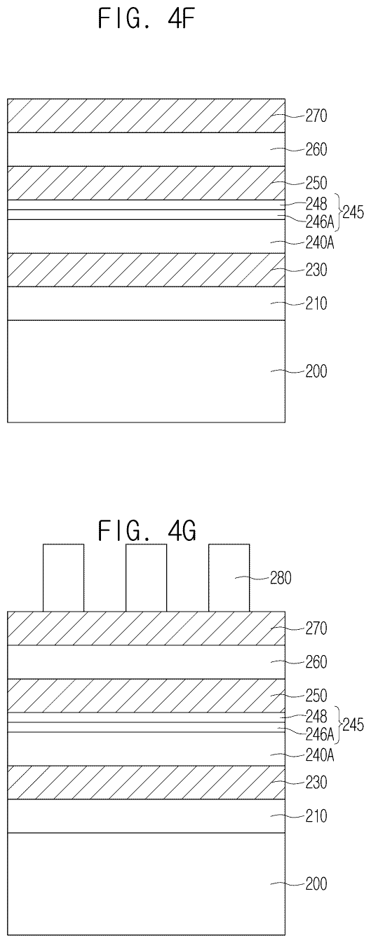

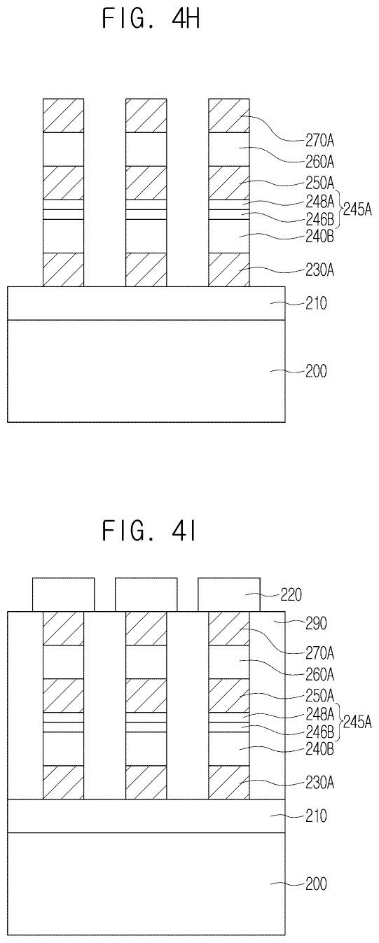

FIGS. 4A to 4I are cross-sectional views illustrating a semiconductor device and a method for fabricating the same in accordance with an embodiment of the present disclosure.

First, the method for fabricating the same will be described.

Referring to FIG. 4A, a substrate 200 in which a predetermined lower structure is formed may be provided. The substrate 200 may include diverse required circuits. A first interconnection 210 may be formed over the substrate 200. The first interconnection 210 may be formed by forming a gap-fill layer (not shown) having a trench for forming the first interconnections 210 over the predetermined structure, and depositing a conductive layer for forming the first interconnections 210 in the trench. The first interconnections 210 may include diverse conductive materials, for example, metals such as platinum (Pt), tungsten (W), aluminum (Al), copper (Cu), tantalum (Ta) and the like, metal nitrides such as titanium nitride (TiN), tantalum nitride (TaN) and the like, or a combination thereof, and the first interconnections 210 may have a single-layer structure or a multi-layer structure.

Subsequently, the first electrode layer 230 may be formed over the first interconnections 210. The first electrode layer 230 may be realized as a titanium nitride (TiN) thin layer. Subsequently, a boron-containing amorphous silicon layer may be formed as an initial selector layer 240 over the first electrode layer 230. The initial selector layer 240 may be formed by depositing an amorphous silicon layer through a Low-Pressure Chemical Vapor Deposition (LPCVD) process using a silicon source gas and a boron source gas. Here, the silicon source gas may include silane (SiH₄), dichlorosilane (SiH₂Cl₂), tetrachlorosilane (SiCl₄), trichlorosilane (SiHCl₃), or a mixture thereof, and the boron source gas may include diborane (B₂H₆), trimethylborane (B₃H₉), boron trimethyl ester (B(OCH₃)₃), boron trifluoride (BF₃), or a mixture thereof. For example, a silane gas (SiₓH_{y}), such as silane (SiH₄) and diborane (B₂H₆), may be mixed and used to form the initial selector layer 240, and the low-pressure chemical vapor deposition process may provide a uniform thin layer and a low defect rate to improve the performance of the semiconductor device. Silane may be used as a main source of the silicon element, and diborane may be mixed with silane and utilized to form an amorphous silicon layer and improve doping uniformity.

Before the LPCVD process begins, the chamber may be made into a vacuum state, and the amorphous silicon layer may be formed under the conditions of a temperature of approximately 300 to approximately 400° C. and a low pressure state, for example, approximately 10 to 100 mTorr. The boron doping concentration may be adjusted to a desired level by controlling the flow rate ratio of the silicon source gas and the boron source gas. Through this process, the boron source gas and the silicon source gas may react with each other to form a uniform amorphous silicon layer over the substrate.

Further, the thickness and doping distribution of the layer may be maintained uniformly by precisely controlling the deposition time and the gas flow rate. The structural stability of the layer may be increased and the boron doping distribution may be optimized by additionally applying an annealing process to the formed amorphous silicon layer. As a result of this process, a uniform boron-doped amorphous silicon layer may be efficiently formed.

Subsequently, referring to FIG. 4B, a first dopant, for example, germanium (Ge), may be ion-implanted into the initial selector layer 240 to form a first dopant-doped selector layer 240A. In addition to germanium (Ge), the first dopant may include a Group-14 element of the periodic table, for example, carbon (C), silicon (Si), or tin (Sn). The initial selector layer 240 may be ion-implanted by ionizing the germanium atoms and then making the germanium ions collide with the initial selector layer at a high speed and doping the initial selector layer with the germanium ions. During the ion implantation, an ion implantation energy condition of approximately 20 to 80 kilo-electron volt (keV) and a concentration condition of approximately 1×10¹³ to 1×10¹⁵ cm² may be adopted, and the ion implantation process may be performed at a room temperature to minimize the thermal damage. The implanted germanium (Ge) ions may be unevenly distributed in the initial selector layer 240 and may be rearranged through a subsequent annealing process. The annealing process may be performed at a temperature of approximately 300 to 400° C. for several minutes to several hours to uniformly diffuse the implanted germanium (Ge) ions into the initial selector layer. This annealing process may provide a structural stability to the first dopant-doped selector layer 240A and optimize the electrical characteristics of the first dopant-doped selector layer 240A. The first dopant-doped selector layer 240A may have a thickness of approximately 50 to 150 Å, in a particular embodiment a thickness of approximately 80 to 120 Å, and in a further embodiment a thickness of approximately 90 to 110 Å.

The ion implantation of germanium (Ge) may contribute to reducing the structural damage of the first dopant-doped selector layer 240A compared to a general arsenic-doped silicon oxide (As—SiO₂) because the atomic radius and physical characteristics of germanium (Ge) are similar to those of silicon (Si) but have less aggressive effects. Additionally, the resistance map uniformity of the amorphous silicon layer may be further improved through the doping of germanium (Ge). As the resistance map uniformity is improved, the current flow of the selector pattern (240B shown in FIG. 4I) may be stably maintained, and the consistent operation of the selector pattern 240B may be secured.

Since germanium (Ge) has d electrons, the atomic structure of germanium (Ge) is more complicated than that of silicon, which may affect the band structure. The presence of d electrons may contribute to germanium (Ge) having a higher conductivity than that of silicon. Since the atomic radius of germanium (Ge) is approximately 122 pm (picometer), which is greater than the atomic radius of silicon, which is approximately 111 pm, lattice strain may occur when germanium (Ge) is doped into silicon (Si). At a predetermined temperature, the band gap of germanium (Ge), which is approximately 0.66 eV, may be smaller than the band gap of silicon (Si), which is approximately 1.12 eV. Therefore, germanium (Ge) may have more free electrons than silicon (Si) and may have increased conductivity. This characteristic may be advantageous for high-speed devices or high-current applications. For example, when germanium (Ge) is doped with arsenic (As), N-type semiconductor characteristics may be obtained, which may be used for diverse electronic devices, such as transistors, optical devices and the like.

When germanium (Ge) is doped with silicon (Si), lattice strain may occur due to the difference in atomic radii. Since the atomic radius of germanium (Ge) is greater than the atomic radius of silicon (Si), the silicon lattice may be compressed and strained. This strain may change the band structure and conductivity and may improve the electron mobility and the device performance.

Even though the initial selector layer 240 is doped with germanium (Ge), the Eot (Effective Oxide Thickness) and the leakage current range may be maintained at appropriate levels for the operation of the selector pattern 240B. The germanium (Ge) doping process may effectively control the leakage current while improving the conductivity. This is important especially in a semiconductor device that requires a high reliability. Also, doping the initial selector layer 240 with germanium (Ge) may be effective in controlling the initial resistance Rᵢₙᵢ due to the high conductivity and d electrons of germanium (Ge), and the generated selector pattern 240B may operate properly in diverse operation environments. The strong strained lattice structure generated through the germanium (Ge) doping process may make the electrical characteristics of the selector pattern 240B more stable.

The ion implantation process using germanium (Ge) as the first dopant may improve the electrical characteristics and the structural stability of the first dopant-doped selector layer 240A, thereby ultimately realizing a high-performance selector pattern 240B. The germanium (Ge) doping process may provide the selector pattern 240B with superior performance to a typical arsenic-doped silicon oxide (As—SiO₂) in diverse aspects, such as resistance map uniformity, leakage current control, initial resistance adjustment and the like.

Subsequently, referring to FIGS. 4C and 4D, a silicon nitride (SiₓN_{y}, where x ranges from 1 to 3 and y ranges from 1 to 4) layer 246 may be deposited over the first dopant-doped selector layer 240A. The silicon nitride may be Si₃N₄, Si₂N₃, or SiN. The silicon nitride layer 246 may be deposited by Chemical Vapor Deposition (CVD), Physical Vapor Deposition (PVD), Atomic Layer Deposition (ALD), or plasma treatment. The Chemical Vapor Deposition (CVD) may include Plasma Enhanced Chemical Vapor Deposition (PECVD), Low-Pressure Chemical Vapor Deposition (LPCVD), and Thermal Chemical Vapor Deposition (Thermal CVD). In this case, for uniformity of the thickness of the silicon nitride layer 246, atomic layer deposition (ALD) or low-pressure chemical vapor deposition (LPCVD) may be suitable. When a low temperature process is required, plasma enhanced chemical vapor deposition (PECVD) may be suitable, and when the layer stress needs to be controlled, plasma enhanced chemical vapor deposition (PECVD) may be suitable. The deposition method may be selected according to the interface characteristics and process conditions between the first dopant-doped selector layer 240A and the silicon nitride layer 246. Trap sites may be artificially formed in plural in the silicon nitride layer 246 by combining the first dopant-doped selector layer 240A based on an amorphous silicon layer and the silicon nitride layer 246.

Since the first dopant-doped selector layer 240A based on the amorphous silicon layer intrinsically has an amorphous structure, there may be incomplete bonds or defects. These defects may promote the formation of trap sites by inducing a chemical reaction or a structural change around the interface, when the first dopant-doped selector layer 240A contacts the silicon nitride layer. Additionally, the process conditions used in the process of depositing the silicon nitride layer 246 may also have a significant effect on the formation of the trap sites. For example, during the deposition of the nitride through the processes such as chemical vapor deposition (CVD), atomic layer deposition (ALD), and plasma treatment, the deposition temperature, pressure, intensity of plasma and the like may cause delicate defects in the inside of the nitride layer. In particular, the plasma-enhanced chemical vapor deposition (PECVD) process or the atomic layer deposition (ALD) process may promote a reaction at a high energy state, and the energy may cause a change in the local electron density or bonding distortions in the inside of the silicon nitride layer.

Further, a metal element that is doped into the first dopant-doped selector layer 240A, such as germanium (Ge) or arsenic (As), or metal atoms diffused into the inside of the silicon nitride layer 246 may also contribute to the formation of trap sites. The metal atoms may distort the bonding structure of the nitride layer or create new defects inside. In particular, in instances in which the diffusion length of the metal is long, it may affect the deep interior of the nitride layer, thereby forming more trap sites. The interaction occurring at the interface between the selector layer 240A and the silicon nitride layer 246 may also function to induce the formation of trap sites. The chemical reaction at the interface may cause structural nonuniformity (for example, irregularities), which causes a plurality of trap sites to be formed around the interface.

The trap sites in the silicon nitride layer 246 may be formed in plural due to the complex interaction of the structural characteristics and doping state of the selector layer, the composition and process conditions of the silicon nitride layer, and the chemical reaction occurring at the interface, which induces a defect in the silicon nitride layer. These trap sites may function to control the electrical characteristics later and serve as a significant element for improving the performance of the selector pattern 240B.

Referring to FIG. 4E, a first metal nitride layer 248 may be deposited over the deposited silicon nitride layer 246, and as a result, a first metal-doped silicon nitride layer 246A may be formed. Here, the first metal may be titanium (Ti), copper (Cu), silver (Ag), or gold (Au), and these metals may have high chemical stabilities and long metal diffusion lengths.

In the case of the first metal-doped silicon nitride layer 246A, metal doping may be performed at the trap sites that are formed in plural in a silicon nitride (SiₓN_{y}, where x ranges from 1 to 3 and y ranges from 1 to 4), such as Si₃N₄, Si₂N₃, or SiN. The first metal having a long metal diffusion length may be doped into the trap sites that are formed in plural through the process of FIG. 4D. This may enhance the conductive characteristics of the selector pattern 240B, and the metal atoms may be effectively diffused into the silicon nitride by the N₂ plasma formed by the atomic layer deposition (ALD) process and the thermal effect, thereby forming an artificial conductive bridge layer.

Silicon nitride (SiₓN_{y}, where x ranges from 1 to 3 and y ranges from 1 to 4) may have a structure that inherently contains defects, and these defects may serve as trap sites. These trap sites may provide a path for the metal atoms to migrate and settle into the inside of the nitride layer. A metal nitride may be deposited over the silicon nitride layer through an atomic layer deposition (ALD) process, and during this process, the metal atoms may be diffused into the silicon nitride layer. The N₂ plasma and the thermal effect may play an important role in the diffusion process. N₂ plasma may be in a state in which nitrogen atoms and electrons have high energy, and this energy may be transferred to the metal atoms to provide power for the metal atoms to be diffused deeper. At the same time, the process temperature of approximately 250° C. to 400° C. may increase the kinetic energy of the metal atoms, thereby promoting diffusion into the silicon nitride. When the metal atoms enter the interior of the silicon nitride layer, they may partially distort the bonding structure of the nitride or may be bonded to the trap sites, which may impart new physical and electrical characteristics to the inside of the nitride layer.

When the metal atoms are diffused into the silicon nitride layer 246 and evenly distributed to the trap sites, these metal atoms may form a conductive bridge layer, which is an electron conductive path. The metal atoms may be adsorbed or bonded to the trap sites, and metal clusters or nano-sized metal particles may be formed in the silicon nitride layer 246. When a sufficient number of the metal atoms accumulate along the locations of defects in the silicon nitride layer 246, they may be coupled to each other to form a metal bridge and a first metal-doped silicon nitride layer 246A. This bridge may serve as a path through which electrons may migrate. When a specific voltage is applied or through a subsequent process including an additional process, such as an annealing process or a plasma treatment, the metal clusters may be further coupled and stabilized, thereby forming a continuous conductive path in the first metal-doped silicon nitride layer 246A. The conductive bridge layer may provide a main path through which current may flow in the first metal-doped silicon nitride layer 246A.

Since the bridge layer may allow current to flow through the metal bridge, the electrical conductivity of the selector pattern 240B may be significantly improved. Also, the formation and distribution of the conductive bridge layer may play an important role in controlling the switching voltage and the threshold voltage Vₜₕ of the selector pattern 240B. The metal bridge layer may provide a path through which the current may flow stably while maintaining the structural stability of the first metal-doped silicon nitride layer 246A, thereby increasing the durability and reliability of the selector pattern 240B.

The first metal nitride layer 248 may include a metal nitride that is deposited through, for example, an atomic layer deposition (ALD) process, such as titanium nitride (TiN), copper nitride (CuN), silver nitride (AgN) or gold nitride (AuN).

In an embodiment in which the first metal nitride is titanium nitride (TiN), the titanium nitride (TiN) may improve the transfer of an electrical signal of the selector pattern 240B because titanium nitride (TiN) has excellent electrical conductivity. Also, titanium nitride (TiN) may provide high thermal stability and oxidation resistance to maintain the structural stability in a high-temperature process. By using titanium nitride (TiN) as the first metal nitride, the disclosed embodiments may effectively control the trap sites at the interface with the silicon nitride layer 246 due to the N₂ plasma and the thermal effect, and this may optimize the switching characteristics of the selector pattern 240B. Titanium nitride (TiN) may react with the silicon nitride of the silicon nitride layer 246 to form a titanium-doped silicon nitride interface, which may enhance the conductive bridge function. Titanium nitride (TiN) may also provide high reliability and stability to the selector pattern 240B, and may stably control the threshold voltage Vₜₕ and the forming voltage V_{f} of the selector pattern 240B. By precisely controlling the current flow, performance deterioration may be prevented even in repetitive switching operations.

In an embodiment in which the first metal nitride is copper nitride (CuN), copper may effectively fill the traps of the silicon nitride layer 246 due to the high metal diffusivity of copper. Copper nitride (CuN) may maximize the transfer of an electrical signal due to the low resistance, and may be suitable as a selector material due to the high conductivity and relatively easy doping process. Copper nitride (CuN) may maximize the conductivity due to the low electrical resistance, enabling fast switching of the selector pattern 240B. Also, copper nitride (CuN) may efficiently support the formation of the trap sites and conductive bridges due to the metal diffusion characteristics.

In an embodiment in which the first metal nitride is silver nitride (AgN), silver nitride (AgN) may have a very low resistance and may provide excellent electrical signal transmission. Since silver (Ag) may have a longer diffusion length than copper (Cu), silver (Ag) may maximize the interaction with the trap sites. Silver nitride (AgN) may provide long-term stability by suppressing oxidation and deterioration in a high-temperature environment. Additionally, silver nitride (AgN) may effectively promote the formation of a conductive bridge to enable fast switching of the selector pattern 240B, reduce the power consumption of the selector pattern 240B due to the low resistance, and maintain stable electrical characteristics.

In an embodiment in which the first metal nitride is gold nitride (AuN), gold (Au) has excellent chemical stability, high corrosion-resistance, and excellent thermal stability because gold (Au) has a slow diffusion rate compared to other metals. Therefore, gold nitride (AuN) may provide high conductivity to improve the reliability and performance of the selector pattern 240B. Gold nitride (AuN) may maximize the long-term stability of the selector pattern 240B and maintain the performance even in the high-temperature and harsh environments. Additionally, gold nitride (AuN) may uniformly maintain the electrical characteristics of the selector pattern 240B and minimize performance deterioration of the selector pattern 240B even during the repeated switching operations.

For example, when the first metal nitride is titanium nitride (TiN), it may form a titanium-doped silicon nitride (SiₓN_{y}—Ti, where x ranges from 1 to 3 and y ranges from 1 to 4) layer under the conditions of the N₂ plasma and the annealing process to enhance the operation of the selector pattern 240B. Trap sites and metal diffusions may be combined at the interface between the first metal-doped silicon nitride layer and the first metal nitride layer to form an artificial conductive bridge layer. For example, the intermediate layer 245 including the first metal-doped silicon nitride layer 246A and the first metal nitride layer 248 may serve as the conductive bridge layer. This interface may serve as a core region of electrical switching during the operation of the selector pattern 240B.

The conductive bridge layer may be formed by a combination of the first metal nitride and silicon nitride, and may be formed by using the N₂ plasma and the thermal effect through an atomic layer deposition (ALD) process. The conductive bridge layer may provide a path that may efficiently transfer the current generated during a switching operation, thereby increasing the response rate and accuracy of the switching operation. The conductive bridge layer may function as a serving layer, which controls and stabilizes the electrical characteristics at the interface. The conductive bridge layer may maintain the reliability of the selector pattern 240B by alleviating the electrical stress and the thermal effect occurring during the switching operation. The conductive bridge layer, which is a combination of the first metal-doped silicon nitride layer 246A and the first metal nitride layer 248, may form a conductive path containing metal atoms, thereby allowing the current to flow stably. This may significantly improve the conductivity of the selector pattern 240B and allow the selector pattern 240B to operate stably during the operation.

This conductive bridge layer may provide a higher electrical conductivity than that of a typical silicon nitride-only structure. This may allow the selector pattern 240B to stably transfer a higher current when the selector pattern 240B receives a voltage applied thereto. In order to design the selector pattern 240B to operate only at a predetermined voltage, the threshold voltage Vₜₕ and the forming voltage V_{f} may have to be precisely controlled, and the conductive bridge layer may set these voltage values to desired levels by controlling the electrical characteristics and current distribution at the interface. When the switching operation is performed repeatedly, the electrical stress and thermal damage at the interface may accumulate. However, the conductive bridge layer may disperse this damage, thereby greatly improving the reliability and durability of the selector pattern 240B.

The atomic layer deposition (ALD) process may be performed at a temperature of approximately 250° C. to 400° C., for example, at a temperature of approximately 270° C. to 350° C. Appropriate energy may be required for metal atoms to be effectively diffused into the trap sites in silicon nitride (SiₓN_{y}). At a temperature equal to or higher than approximately 250° C., metal atoms may be diffused actively, which allows smooth doping into the trap sites. In contrast, in instances in which the temperature exceeds approximately 400° C., structural defects may occur due to the excessive diffusion of the metal atoms or a reaction between the layers. Thus performing the ALD process at the indicated temperature ranges (approximately 250° C. to 400° C., or alternatively, approximately 270° C. to 350° C.) may ensure thermal stability in both the silicon nitride layer 246 and the metal nitride layer 248. Both materials may have to maintain the structural stability at a high temperature, and when the temperature is too high or too low, there is a risk that the physical and chemical characteristics of the materials may deteriorate. Due to the characteristics of the atomic layer deposition (ALD) process, the deposition may be performed on the atomic basis for each layer, and only when an appropriate temperature is maintained, the reactants may be uniformly adsorbed and reacted on the surface to form a high-quality deposition layer. In particular, the temperature range of approximately 270° C. to 350° C. may be a condition that a metal precursor and the N₂ plasma, which is a reaction gas, may optimally react with each other, and the metal nitride layer deposited at this temperature may have high uniformity and bonding stability.

The layer deposited at the appropriate temperature of approximately 250° C. to 400° C. may have neither excessive nor insufficient nitrogen bonds and may maintain high electrical conductivity through uniform metal doping. Additionally, in the process of forming the intermediate layer 245 including the first metal-doped silicon nitride layer 246A and the first metal nitride layer 248, the interface between the first metal-doped silicon nitride layer 246A and the first metal nitride layer 248 may play an important role. The temperature range of approximately 250° C. to 400° C., or in a particular embodiment approximately 270° C. to 350° C., may appropriately control the adhesive force between the two materials and the chemical reaction at the interface, thereby contributing to forming a structurally stable layer. The temperature range of approximately 250° C. to 400° C., or in the particular embodiment approximately 270° C. to 350° C., may provide optimal conditions for ensuring effective diffusion of the metal atoms, thermal stability of the materials, maximization of electrical conductivity, and deposition quality, and maximizing the physical and chemical characteristics of the first metal-doped silicon nitride layer 246A and the first metal nitride layer 248 while preventing unnecessary defects during the process. The deposition of the atomic layer deposition (ALD) process may provide high electrical conductivity and heat resistance and ensure the structural stability of the intermediate layer 245.

For example, an annealing process may be performed after the deposition of the first metal nitride layer 248 including titanium nitride (TiN), copper nitride (CuN), silver nitride (AgN) or gold nitride (AuN). This process may play an important role in effectively diffusing the metal atoms into the silicon nitride layer 246. The annealing process may increase the kinetic energy of the metal atoms and facilitate the metal to penetrate deeper into the inside of the silicon nitride layer 246. Also, a plasma process may be utilized to more efficiently perform the metal doping. The plasma process may utilize high-energy ions to promote a reaction between the metal atoms and the surface of the silicon nitride layer 246 and may increase the quality (for example, strength) of bonding the metal to the trap sites of the silicon nitride layer 246. In particular, the N₂ plasma may enhance the chemical bond between nitrogen and the metal and may facilitate the metal atoms to be selectively doped into the trap sites in the silicon nitride layer 246.

Through the additional process, the metal may be artificially doped into the trap sites in the silicon nitride layer 246. This may form a conductive bridge layer much more efficiently than natural diffusion. The electrical characteristics of the first metal-doped silicon nitride layer 246A that is formed consequently may be improved, and the performance of the selector pattern 240B may be optimized.

In this way, the intermediate layer 245 may have a multi-layer structure, and the first metal-doped silicon nitride layer 246A and the first metal nitride layer 248 may be included in each layer in the multi-layer structure. Also, the intermediate layer 245 may have a thickness of approximately 10 to 100 Å, in a particular embodiment a thickness of approximately 30 to 80 Å, and in a further embodiment a thickness of approximately 40 to 60 Å. When the intermediate layer 245 has an excessively thin thickness of less than approximately 10 Å, the density of trap sites may not be sufficient so that the conductive bridge may not be stably formed, and the switching operation may become unstable or the reproducibility may be poor. Also, when the intermediate layer 245 has an excessively thick thickness of more than approximately 100 Å, the metal ion diffusion path required to form the conductive bridge may become longer and consequently increase the switching voltage and slow down the response rate, and as the probability and incidence of current leakage increases, the efficiency of the selector pattern 240B may decrease.

Subsequently, referring to FIG. 4F, a second electrode layer 250, a memory layer 260, and a third electrode layer 270 may be formed over the intermediate layer 245. The second electrode layer 250 and the third electrode layer 270 may be formed by depositing a conductive material. The second electrode layer 250 may be realized as a single layer of a titanium nitride (TiN) thin layer, and the second electrode layer 250 may be realized by stacking a carbon (C) thin layer and a titanium nitride (TiN) layer. The carbon (C) thin layer may be formed at the interface between the first dopant-doped selector layer 240A and the titanium nitride (TiN) layer, thereby improving the interface characteristics between the electrodes. Also, a silicon nitride (SiN) thin layer may be formed between the first electrode layer 230 and the first dopant-doped selector layer 240A, and a carbon (C) thin layer may be formed between the first dopant-doped selector layer 240A and the second electrode layer 250.

A memory layer 260 may be formed between the first dopant-doped selector layer 240A and the third electrode layer 270, and the memory layer 260 may include a variable resistance layer. The variable resistance layer may store data by changing the resistance state according to the voltage, and may perform a significant function as a memory element.

The third electrode layer 270 may be formed over the second electrode layer 250 and the memory layer 260, and the third electrode layer 270 may be generally formed of a material that may endure a high-temperature annealing process and have excellent conductivity. The third electrode layer 270 may be formed by using a metal deposition process or a sputtering method. To be specific, the third electrode layer 270 may be formed by depositing a conductive metal thin layer, such as titanium nitride (TiN), tungsten (W), copper (Cu), or aluminum (Al).

According to an embodiment, the processes may be selected to maintain high deposition uniformity and conductivity in forming the third electrode layer 270, and here, a metal layer may be formed to have a desired thickness through a plasma sputtering process or a chemical vapor deposition (CVD) process. After the third electrode layer 270 is formed, an additional annealing process or a patterning process may be performed to provide optimal electrical connection characteristics in the semiconductor device.

Referring to FIG. 4G, a hard mask layer 280 may be formed over the third electrode layer 270. The hard mask layer 280 may be formed by forming a material layer for the hard mask layer 280 and a photoresist pattern (not shown) and etching the material layer for the hard mask layer 280 with the photoresist pattern used as an etching barrier. The hard mask layer 280 may function as an etching barrier during an etching process for forming a memory cell MC and may include diverse materials capable of securing an etching selectivity with respect to the memory cell MC. For example, the material layer for the hard mask layer 280 may have a single-layer structure or a multi-layer structure including diverse dielectric materials, such as silicon oxide, silicon nitride, and silicon oxynitride.

Referring to FIG. 4H, a memory cell MC including the third electrode layer pattern 270A, the memory layer pattern 260A, the second electrode layer pattern 250A, the selector pattern 240B, and the first electrode layer pattern 230A may be formed by etching the third electrode layer 270, the memory layer 260, the second electrode layer 250, the first and second dopant-doped selector layer 240B, and the first electrode layer 230 with the hard mask layer 280 used as an etching barrier. This etching process may be a process of selectively removing part of each layer to form the remaining portion of the layer into a desired shape and forming electrical and physical isolation between the layers. In this process, the hard mask layer 280 may facilitate protecting the underlying layer and formation of a proportionally precise pattern.

According to this embodiment of the present disclosure, the hard mask layer 280 may be removed in the etching process of the memory cell MC, but according to another embodiment of the present disclosure, part or all of the hard mask layer 280 may remain and may be removed in a planarization process described below.

Referring to FIG. 4I, an inter-layer dielectric layer 290 may be formed between the memory cells MC. The inter-layer dielectric layer 290 may be formed to have a thickness that sufficiently fills the space between the memory cells MC and covers the upper portion. The inter-layer dielectric layer 290 may have a single-layer structure or a multi-layer structure including diverse dielectric materials, such as silicon oxide, silicon nitride, or a combination thereof.

Subsequently, a planarization process, such as a Chemical Mechanical Polishing (CMP) process, may be performed onto the inter-layer dielectric layer 290 until the upper surface of the memory cell MC is exposed. In instances in which the hard mask layer 280 is not completely removed but remains in the aforementioned process of etching the memory cell MC, the hard mask layer 280 may thereafter be removed since the planarization process is performed until the upper surface of the memory cell MC is exposed in this process.

Subsequently, a plurality of second interconnections 220 extending in the second direction intersecting with the first direction, for example, the second direction of FIG. 1A, while coupled to the upper surface of the memory cell MC over the memory cell MC and the inter-layer dielectric layer 290 may be formed. The second interconnections 220 may be formed by depositing a conductive material and patterning the conductive material, and the space between the second interconnections 220 may be filled with a dielectric material (not shown).

The semiconductor device in accordance with the embodiment of the present disclosure, as illustrated in FIG. 4I, may be fabricated by the process described above.

Referring back to FIG. 4I, the semiconductor device in accordance with the embodiment of the present disclosure may include a structure in which an intermediate layer pattern 245A including a first metal-doped silicon nitride layer pattern 246B and a first metal nitride layer pattern 248A is formed over the selector pattern 240B including the first dopant-doped amorphous silicon layer. The semiconductor device in accordance with the embodiment of the present disclosure may include a substrate 200, and a first interconnection 210, a first electrode layer pattern 230A, a selector pattern 240B including a first dopant-doped amorphous silicon layer, an intermediate layer pattern 245A including a first metal-doped silicon nitride layer pattern 246B and a first metal nitride layer pattern 248A, a second electrode layer pattern 250A, a memory layer pattern 260A, a third electrode layer pattern 270A, and a second interconnection 220 that are sequentially formed over the substrate 200, and the semiconductor device may include an inter-layer dielectric layer 290 covering the space between the memory cells.

The process structure of FIG. 4I may be substantially the same as the process structures of FIGS. 1A and 1B described above. Namely, the substrate 200, the first interconnection 210, the first electrode layer pattern 230A, the selector pattern 240B, the second electrode layer pattern 250A, the memory layer pattern 260A, the third electrode layer pattern 270A, and the second interconnection 220 may correspond to the substrate 100, the first interconnection 110, the first electrode layer 130, the selector layer 140, the second electrode layer 150, the memory layer 160, the third electrode layer 170, and the second interconnection 120 shown in FIGS. 1A and 1B, respectively. Therefore, a detailed description on the portion corresponding to the process structure of FIGS. 1A and 1B described above will be omitted.

When the selector pattern 240B of the semiconductor device is formed in accordance with the embodiment of the present disclosure, the selector pattern 240B adopting a Conductive Bridging Random Access Memory (CBRAM) mechanism may be formed by forming the intermediate layer pattern 245A including the first metal-doped silicon nitride layer pattern 246B and the first metal nitride layer pattern 248A over the selector pattern 240B. CBRAM may store data by forming and removing a conductive bridge based on the ion migration and an electrochemical reaction. Similarly, the selector pattern 240B in accordance with the embodiment of the present disclosure may provide a diffusion path for metal ions through the trap sites artificially formed in the silicon nitride layer to induce the formation of a conductive bridge. Accordingly, the selector pattern 240B can operate based on ion mobility, as metal ions diffuse within the silicon nitride layer to form or dissolve a conductive bridge.

The intermediate layer pattern 245A in accordance with the embodiment of the present disclosure may function as a serving layer to form and stabilize a conductive bridge in the selector pattern 240B and control the conductivity of the selector pattern 240B. The intermediate layer pattern 245A functioning as a serving layer may be formed by using the N₂ plasma and the thermal effect in the atomic layer deposition (ALD) process, and through this process, embodiments may precisely control the conductive bridge by adjusting the forming voltage V_{f} and threshold voltage Vₜₕ of the selector pattern 240B in accordance with selected conditions and target outcomes.

According to the embodiment of the present disclosure, the switching characteristics of the selector pattern 240B may be improved, as the metal ions migrate and are combined along the trap sites to form a conductive bridge. In particular, by using a metal with a long metal diffusion length, the formation and breakdown of the bridge may be performed more quickly and stably. As a result, the selector pattern 240B in accordance with the embodiment of the present disclosure may be adjusted to operate even at a low voltage, which may contribute to reducing power consumption and increasing the efficiency of the device. Additionally, by precisely controlling the conductive bridge, the current may be precisely controlled in the switching operation of the device, and the device may operate stably even under the thermal and electrical stresses through the optimization of the intermediate layer 245A and the trap sites.

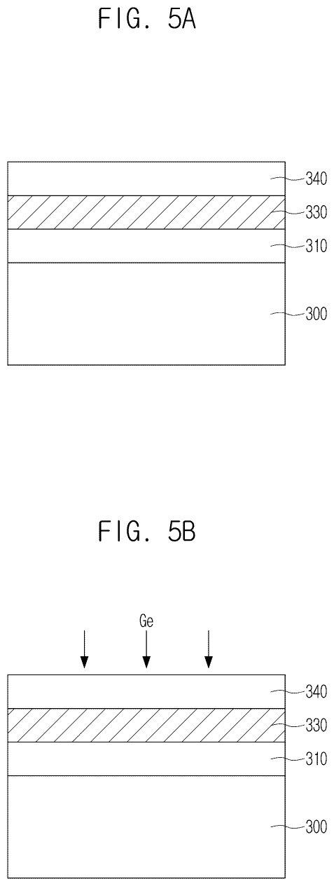

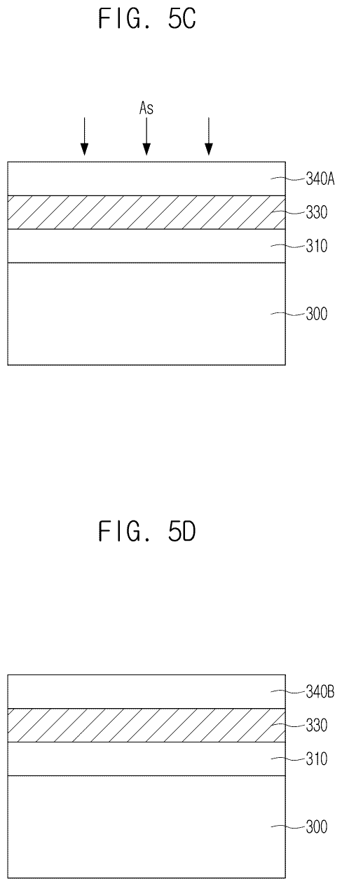

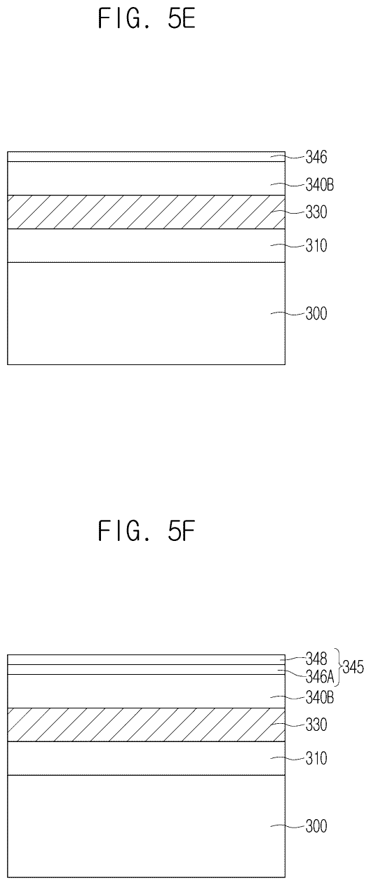

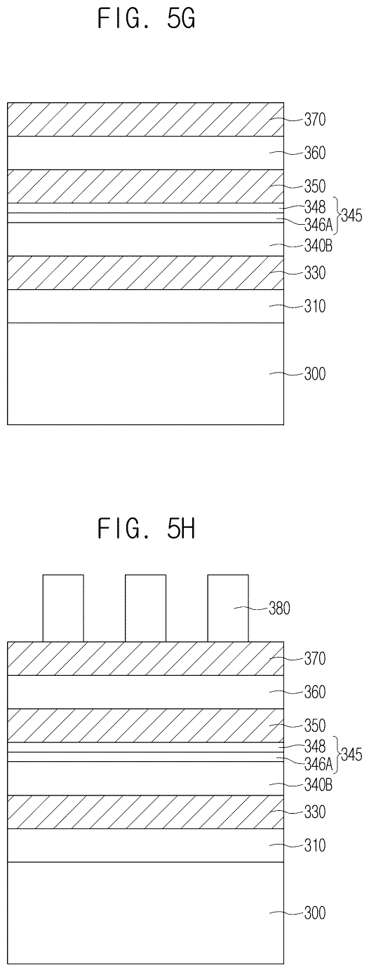

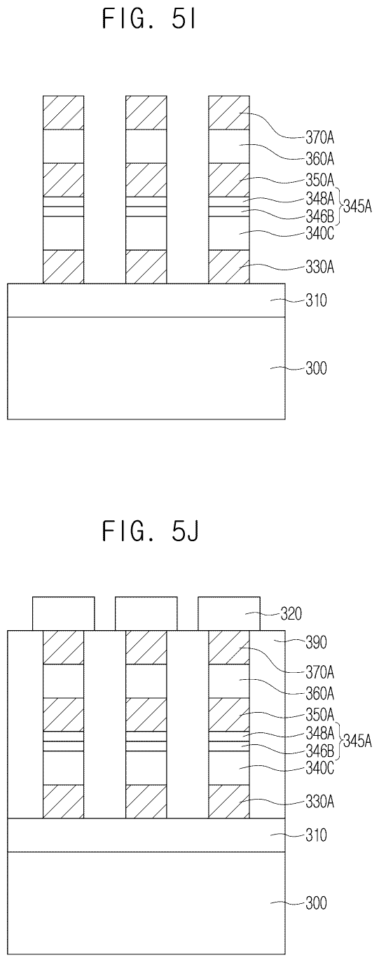

FIGS. 5A to 5J are cross-sectional views illustrating a semiconductor device and a method for fabricating the same in accordance with another embodiment of the present disclosure.

First, the method for fabricating the semiconductor device will be described.

Referring to FIG. 5A, a substrate 300 having a predetermined lower structure formed therein may be provided. A first interconnection 310 may be formed over the substrate 300. Subsequently, a first electrode layer 330 may be formed over the first interconnection 310. Subsequently, a boron-containing amorphous silicon layer may be formed as an initial selector layer 340 over the first electrode layer 330.

Subsequently, referring to FIG. 5B, a first dopant, for example, germanium (Ge), may be ion-implanted into the initial selector layer 340 to form a first dopant-doped selector layer 340A. The first dopant may include, a Group-14 element of the periodic table, for example, carbon (C), silicon (Si), or tin (Sn) in addition to germanium (Ge).

Subsequently, referring to FIGS. 5C and 5D, a second dopant, for example, arsenic (As), may be ion-implanted into the first dopant-doped selector layer 340A to form a first and second dopant-doped selector layer 340B. The second dopant may include a Group-15 element of the periodic table, such as nitrogen (N), phosphorus (P), or antimony (Sb), in addition to arsenic (As). In a particular embodiment, the first dopant may include germanium (Ge), and the second dopant may include arsenic (As), phosphorus (P), or antimony (Sb). In a further embodiment, the second dopant may include arsenic (As).

In particular, phosphorus (P) or antimony (Sb) may be ion-implanted as the second dopant together with arsenic (As), or instead of arsenic (As). The first and second dopant-doped selector layer 340B may be formed by ion-implanting germanium (Ge), which is a Group-14 element, as the first dopant and ion-implanting arsenic (As), phosphorus (P), or antimony (Sb), or a combination of two or more of them as the second dopant into the initial selector layer 340. This method may provide a basis whose physical characteristics are optimized by using germanium (Ge) as the first dopant, while realizing diverse electrical characteristics by combining arsenic (As), phosphorus (P), or antimony (Sb) as the second dopant. Since arsenic (As) is advantageous in terms of electron mobility and doping efficiency and phosphorus (P) and antimony (Sb) have similar chemical characteristics to those of arsenic (As), they may provide complementary electrical characteristics to each other. In particular, since phosphorus (P) has a high activation efficiency after implantation due to a relatively small atomic radius and high electronegativity, the disclosed embodiment may enable performance of a precise doping process, compared to a case where phosphorus (P) is combined with arsenic (As). Antimony (Sb) has a greater atomic radius than arsenic (As) but has similar chemical characteristics, and may form a stable current path even at a high doping concentration. Also, the first and second dopant-doped selector layer 340B may include two or more combinations selected from the group including germanium (Ge), arsenic (As), phosphorus (P), and antimony (Sb).

The ion implantation process of the second dopant may be performed in a direction substantially perpendicular to the surface of the substrate 300, and a tilted ion implantation process may also be performed. Also, the ion implantation process may be performed repeatedly (for example, several times). By ion-implanting the second dopant such as arsenic (As) into an amorphous silicon layer, electrical characteristics may be imparted to the fabricated semiconductor device. The characteristics of the semiconductor device may be appropriately changed by changing the concentration of the first and second dopant that are ion-implanted. By adjusting the ion implantation energy and angle, the disclosed embodiments may control the concentration of the dopant and penetrate the dopant to a desired depth. The concentration of the dopant may be controlled according to the implantation conditions, such as energy, implantation time, and ion implantation rate, and for example, the concentration of the dopant may be controlled in a range of approximately 10% to 50% according to the implantation conditions. A high concentration of dopant may contribute to forming a current path more easily, but on the other hand, it may increase the leakage current. Therefore, it is desirable to control the concentration of the dopant in the above range. The ion implantation process may be repeated several times to evenly distribute the dopant. The repetition of this process may ensure that the conductive path is formed more stably in the amorphous silicon layer.

The dopant ions implanted during the ion implantation process may impact the crystal structure in the silicon layer due to their high energy. In particular, in instances in which a Group-15 element such as arsenic (As), phosphorus (P), or antimony (Sb) is implanted as a dopant into the amorphous silicon layer, a local recrystallization phenomenon may occur at the implanted location. This re-crystallization may help the conductive path to be formed more easily. This may mainly improve the conduction characteristics of the selector element in the on-state by further activating the conductive path. The ion implantation process may control the electrical characteristics of the semiconductor device by implanting the second dopant into the amorphous silicon layer, inducing the conductive path to be formed based on the implanted dopant. This may give the selector desired current-voltage characteristics and increase the ease of forming the conductive path.

The implantation damage caused by ion-implanting germanium (Ge), which is a Group-14 element of the periodic table, and arsenic (As), which is a Group-15 element, into the initial selector layer 340 may be relatively small compared to that caused by the implantation of lighter or more aggressive dopants such as boron (B) or phosphorus (P). When arsenic and germanium (Ge) are doped into a silicon layer, defects that may occur in a solid material may be minimized. Therefore, the electrical characteristics of the finally formed selector pattern 340C may be stable and uniform. Also, the resistance map uniformity which indicates that the doped material is uniformly distributed in the first and second dopant-doped selector layer 340B may be improved. This may improve the electrical uniformity of the finally formed selector pattern 340C and facilitate reducing the performance variation. Also, due to the doping of germanium (Ge) and arsenic (As), the Eot and leakage current range may be appropriately maintained, and the Eot may not increase. This is advantageous in obtaining desired electrical characteristics by adjusting the Eot and leakage current range values.

Doping of germanium (Ge) and arsenic (As) may play an important role in improving the performance of the selector pattern 340C including an amorphous silicon layer containing boron and controlling the electrical characteristics of the selector pattern 340C, and in particular, the doping of germanium (Ge) and arsenic (As) may maximize the efficiency of the selector pattern 340C through a uniform resistance distribution and an appropriate leakage current, the Eot, and the adjustment of the leakage current range, and may provide characteristics appropriate for industrially significant applications.

According to this embodiment of the present disclosure, germanium (Ge), which is a Group-14 element of the periodic table, may be ion-implanted first into the initial selector layer 340 as the first dopant, and then arsenic (As), which is a Group-15 element, may be ion-implanted as the second dopant subsequently. However, the sequence of the ion implantation may not be limited thereto. For example, even when arsenic (As), which is a Group-15 element, is ion-implanted into the initial selector layer 340 as the first dopant and germanium (Ge), which is a Group-14 element, is ion-implanted as the second dopant, substantially the same effect may be obtained.

The first and second dopant-doped selector layer 340B may have a thickness of approximately 50 to 150 Å, in a particular embodiment a thickness of approximately 80 to 120 Å, and in a further embodiment a thickness of approximately 90 to 110 Å. In instances in which the first and second dopant-doped selector layer 340B is too thin, sufficient charges may not be trapped, which may lower the resistance in the off-state and increase the leakage current. In instances in which the first and second dopant-doped selector layer 340B is too thick, the conductive path may become excessively long in the on-state, which may reduce the current flow. Further, when the thickness of the first and second dopant-doped selector layer 340B is too thin, switching may become unstable and resistance fluctuation may become severe. When the thickness of the first and second dopant-doped selector layer 340B is too thick, the switching rate may be reduced. Since the first and second dopant-doped selector layer 340B has a thickness of approximately 50 to 150 Å, the current flow may be optimized by balancing the formation of the charge traps and the conductive path, effectively controlling the resistance and maintaining a fast switching rate while ensuring a stable switching operation.

The ion implantation process of the second dopant described with reference to FIGS. 5C and 5D may be omitted in the process of realizing the selector pattern 340C in accordance with the embodiment of the present disclosure. Selected embodiments may enable fabrication of a semiconductor device suitable for a particular purpose and characteristics only with an amorphous silicon layer into which a first dopant including a Group-14 element of the periodic table is implanted as the selector pattern 340C. However, when a second dopant including a Group-15 element of the periodic table is additionally implanted, a conductive path may be formed more easily, and thus the electrical characteristics of the selector pattern 340C may be enhanced.

Subsequently, referring to FIGS. 5E and 5F, a silicon nitride (SiₓN_{y}, where x ranges from 1 to 3 and y ranges from 1 to 4) layer 346 may be deposited over the first and second dopant-doped selector layer 340B. The silicon nitride may be Si₃N₄, Si₂N₃, or SiN.

Subsequently, a first metal nitride layer 348 may be deposited over the deposited silicon nitride layer 346, thereby forming a first metal-doped silicon nitride layer 346A. The first metal may be titanium (Ti), copper (Cu), silver (Ag), or gold (Au), and these metals may have high chemical stabilities and long metal diffusion lengths.

In the case of the first metal-doped silicon nitride layer 346A, metal doping may be performed at the trap sites formed in plural in silicon nitride (SiₓN_{y}, where x ranges from 1 to 3 and y ranges from 1 to 4), such as Si₃N₄, Si₂N₃, or SiN. Due to this, an intermediate layer 345 that functions as a serving layer and includes the first metal-doped silicon nitride layer 346A and the first metal nitride layer 348 may be formed.

Referring to FIG. 5G, a second electrode layer 350, a memory layer 360, and a third electrode layer 370 may be formed over the intermediate layer 345. The second electrode layer 350 and the third electrode layer 370 may be formed by depositing a conductive material. The second electrode layer 350 may be realized (implemented, formed) as a single layer of a titanium nitride (TiN) thin layer, and may be realized by stacking a carbon (C) thin layer and a titanium nitride (TiN) layer. The carbon (C) thin layer may be formed at the interface between the first and second dopant-doped selector layer 340B and the titanium nitride (TiN) layer, thereby improving the interface characteristics between the electrodes. Also, a silicon nitride (SiN) thin layer may be formed between the first electrode layer 330 and the first and second dopant-doped selector layer 340B, and a carbon (C) thin layer may be formed between the first and second dopant-doped selector layer 340B and the second electrode layer 350.

Subsequently, referring to FIGS. 5H and 5I, a memory cell MC including a third electrode layer pattern 370A, a memory layer pattern 360A, a second electrode layer pattern 350A, an intermediate layer pattern 345A including a first metal-doped silicon nitride layer pattern 346B and a first metal nitride layer pattern 348A, a selector pattern 340C and a first electrode layer pattern 330A may be formed by forming a hard mask layer 380 over the third electrode layer 370, and etching the third electrode layer 370, the memory layer 360, the second electrode layer 350, the intermediate layer 345 including the first metal-doped silicon nitride layer 346A and the first metal nitride layer 348, the first and second dopant-doped selector layer 340B, and the first electrode layer 330 with the hard mask layer 380 used as an etching barrier.

Referring to FIG. 5J, an inter-layer dielectric layer 390 may be formed between the memory cells MC. The inter-layer dielectric layer 390 may be formed to have a thickness that sufficiently fills the space between the memory cells MC and covers the upper portion. Subsequently, a plurality of second interconnections 320 extending in the second direction intersecting with the first direction, for example, the second direction of FIG. 1A, may be formed over the memory cell MC and the inter-layer dielectric layer 390 while coupled to the upper surface of the memory cell MC.

The process may include performing an annealing process at a temperature lower than a temperature of crystallization of the amorphous silicon layer. In accordance with manufacturing processes, a high temperature process that includes a temperature exceeding approximately 400° C. is not usually followed when a variable resistance memory element is fabricated. Instead, low-temperature processes, such as annealing at temperatures below the crystallization point of amorphous silicon (e.g., below 400° C.), are typically used to preserve the amorphous state of the silicon layer in the selector. In instances such as these, the first and second dopant-doped amorphous silicon layer included in the selector pattern 340C in accordance with the embodiment of the present disclosure may exist in an amorphous state in the final result of the process of fabricating the semiconductor device. The amorphous state may lead to uniform electrical properties, predictable behavior, and electrical conductivity.

The semiconductor device in accordance with the embodiment of the present disclosure, as illustrated in FIG. 5J, may be fabricated by the process described above.

Referring back to FIG. 5J, the semiconductor device in accordance with the embodiment of the present disclosure may include a structure in which an intermediate layer pattern 345A including the first metal-doped silicon nitride layer pattern 346B and the first metal nitride layer pattern 348A is formed over the selector pattern 340C including the first and second dopant-doped amorphous silicon layer. The semiconductor device in accordance with the embodiment of the present disclosure may include a substrate 300, and a first interconnection 310, a first electrode layer pattern 330A, a selector pattern 340C including a first and second dopant-doped amorphous silicon layer, an intermediate layer pattern 345A including a first metal-doped silicon nitride layer pattern 346B and a first metal nitride layer pattern 348A, a second electrode layer pattern 350A, a memory layer pattern 360A, a third electrode layer pattern 370A, and a second interconnection 320 that are sequentially formed over the substrate 300, and may include an inter-layer dielectric layer 390 covering the space between the memory cells.

The process structure of FIG. 5J may be substantially the same as the process structures of FIGS. 1A and 1B described above. The substrate 300, the first interconnection 310, the first electrode layer pattern 330A, the selector pattern 340C, the second electrode layer pattern 350A, the memory layer pattern 360A, the third electrode layer pattern 370A, and the second interconnection 320 may correspond to the substrate 100, the first interconnection 110, the first electrode layer 130, the selector layer 140, the second electrode layer 150, the memory layer 160, the third electrode layer 170, and the second interconnection 120 of FIGS. 1A and 1B, respectively. Therefore, a detailed description on the portion corresponding to the process structure of FIGS. 1A and 1B described above will be omitted.

Even with this embodiment of the present disclosure, the effects of the described embodiment of the present disclosure may be obtained as they are. Furthermore, by performing the ion implantation process in the first and second stages, the dopant in the selector pattern 340C may be distributed more uniformly. Accordingly, the characteristics of the selector pattern 340C, such as the threshold switching (TS) rate, may be further improved.

Also, according to the embodiment of the present disclosure, by implanting a Group-14 element, such as germanium (Ge), and a Group-15 element, such as arsenic (As), into the amorphous silicon layer, a selector pattern having superior performance to that of the selector pattern using a general arsenic (As)-doped silicon oxide layer may be provided.

Unique electrical characteristics may be determined compared to a typical selector pattern by forming a strong strain lattice structure in the selector layer based on the difference in the atomic radius and the masses of silicon (Si) and germanium (Ge) and controlling the implantation amount of arsenic (As) that is additionally ion-implanted. This structure may provide high conductivity and unique resistance characteristics, which may maximize the performance of a selector element that requires leakage current or insulation-like characteristics. Also, since the conductivity of germanium (Ge) is higher than that of silicon (Si), more efficient electrical performance may be achieved by controlling the ion implantation amount of germanium (Ge) and appropriately combining the germanium (Ge) with another element that is ion-implanted, and the flexibility of the selector element may be increased through diverse material combinations. In particular, the co-ion implantation of arsenic (As) and germanium (Ge) may customize the operation characteristics of the selector element to reduce leakage current or enhance the insulation characteristics. A selector pattern with superior performance to a selector pattern using a general arsenic (As)-doped silicon oxide layer may be provided by ion-implanting a Group-14 element, such as germanium (Ge), and a Group-15 element, such as arsenic (As) into the amorphous silicon layer.

A strong strain lattice structure may be formed in the selector layer based on the difference in the atomic radii and masses of silicon (Si) and germanium (Ge), and unique electrical characteristics may be determined (or implemented) compared to a typical selector pattern by controlling the implantation amount of arsenic (As) that is additionally ion-implanted. This structure may provide high conductivity and unique resistance characteristics to maximize the performance of the selector element requiring leakage current or insulation-like characteristics. Additionally, since the conductivity of germanium (Ge) is higher than that of silicon (Si), more efficient electrical performance may be achieved by controlling the ion-implanted amount of germanium (Ge) and appropriately combining the germanium (Ge) with another element that is ion-implanted, and the flexibility of the selector element may be increased through diverse material combinations. In particular, the co-ion implantation of arsenic (As) and germanium (Ge) may customize the operation characteristics of the selector element, to reduce the leakage current or enhance the insulation characteristics.

According to the embodiment of the present disclosure, the semiconductor device and the method for fabricating the same may implement diverse electrical characteristics and switching performances through a combination of a first metal-doped silicon nitride and a first metal nitride obtained by an Atomic Layer Deposition (ALD) process in a selector layer structure based on an amorphous silicon layer, and may have improved characteristics of the selector layer by disposing an intermediate layer that includes the first metal-doped silicon nitride and the first metal nitride obtained by the atomic layer deposition (ALD) process at the upper interface of the selector layer to artificially control the forming voltage V_{f} and the threshold voltage Vₜₕ of the selector layer.

While the embodiments of the present disclosure has been described with respect to the specific embodiments, it will be apparent to those skilled in the art that various changes and modifications may be made without departing from the embodiments of the present disclosure as defined in the following claims.

What is claimed is:

1. A semiconductor device comprising:
a plurality of memory cells,
wherein each of the memory cells includes
a memory layer; and
a selector layer formed over the memory layer to select the memory layer, wherein the selector layer includes an amorphous silicon layer that is doped with a dopant including at least one of arsenic (As) and germanium (Ge); and
an intermediate layer, including a first metal-doped silicon nitride and a first metal nitride, formed over the selector layer.

2. The semiconductor device of claim 1, wherein the first metal-doped silicon nitride and the first metal nitride comprise a first metal selected from the group consisting of titanium (Ti), copper (Cu), gold (Au), and silver (Ag).

3. The semiconductor device of claim 1, wherein the dopant includes arsenic (As) and germanium (Ge).

4. The semiconductor device of claim 1, wherein the dopant has a concentration of 10 to 30 wt % in the amorphous silicon layer.

5. The semiconductor device of claim 1, wherein the dopant has a concentration of 30 to 90 wt % in the amorphous silicon layer.

6. The semiconductor device of claim 1, wherein the first metal-doped silicon nitride is Si₃N₄, Si₂N₃ or SiN.

7. The semiconductor device of claim 1, wherein the intermediate layer has a multi-layer structure.

8. The semiconductor device of claim 7, wherein the first metal-doped silicon nitride and the first metal nitride are respectively included in different layers in the multi-layer structure.

9. The semiconductor device of claim 1, wherein the memory cell further includes
a first electrode layer disposed below the selector layer and
a second electrode layer disposed over the selector layer.

10. The semiconductor device of claim 9, wherein at least one of the first electrode layer and the second electrode layer include a titanium nitride (TiN) thin layer.

11. The semiconductor device of claim 9, further comprising:
a silicon nitride (SiN) thin layer between the first electrode layer and the selector layer, and
a carbon (C) thin layer between the selector layer and the second electrode layer.

12. The semiconductor device of claim 1, wherein the selector layer has a thickness of 50 to 150 Å.

13. The semiconductor device of claim 1, wherein the intermediate layer has a thickness of 10 to 100 Å.
